(19) United States
(12) Patent Application Publication
(10) Pub. No.: US 2022/0336734 A1
(43) Pub. Date: Oct. 20, 2022

(54) METHODS OF MANUFACTURING INTEGRATED CIRCUIT DEVICES

(71) Applicant: Everspin Technologies, Inc., Chandler, AZ (US)

(72) Inventors: Sanjeev AGGARWAL, Scottsdale, AZ (US); Kerry NAGEL, Scottsdale, AZ (US); Santosh KARRE, Chandler, AZ (US)

(73) Assignee: Everspin Technologies, Inc., Chandler, AZ (US)

(21) Appl. No.: 17/659,234

(22) Filed: Apr. 14, 2022

Related U.S. Application Data
(60) Provisional application No. 63/175,822, filed on Apr. 16, 2021.

(51) Int. Cl. H01L 43/12; H01L 27/22; H01L 43/02; H01L 43/08

(52) U.S. Cl. CPC H01L 43/12; H01L 27/226; H01L 43/02; H01L 43/08

(57) ABSTRACT

A method of manufacturing an integrated circuit device comprises forming a layer of barrier material on a surface, where the surface includes interlayer dielectric and a feature of a metal layer. The method may also include forming a layer of contact material above the layer of barrier material. The method may further include removing a portion of the layer of barrier material and a portion of the layer of contact material to form a via. Additionally, the method may include depositing magnetoresistive stack above, and in contact with, the via, where a width of the magnetoresistive stack is greater than or equal to a width of the via.

### CROSS-REFERENCE TO RELATED APPLICATIONS

This application claims the benefit of priority from U.S. Provisional Application No. 63/175,822, filed on Apr. 16, 2021, which is incorporated by reference in its entirety.

### TECHNICAL FIELD

The present disclosure relates generally to integrated circuit devices including magnetoresistive devices and methods of fabricating integrated circuit devices.

### INTRODUCTION

Magnetoresistive devices, such as magnetic sensors, magnetic transducers, and magnetic memory cells, include magnetic materials where the magnetic moments of those materials can be varied to provide sensing information or store data. Magnetoresistive devices, spin electronic devices, and spintronic devices are synonymous terms for devices that make use of effects predominantly caused by electron spin. Magnetoresistive memory devices are used in numerous information devices to provide non-volatile, reliable, radiation resistant, and high-density data storage and retrieval. The numerous magnetoresistive devices may include, but are not limited to, Magnetoresistive Random Access Memory (MRAM), magnetic sensors, and read/write heads for disk drives.

Manufacturing magnetoresistive devices includes a sequence of processing steps where multiple layers of materials are deposited and patterned to form a magnetoresistive stack and the electrodes used to provide electrical connections to the magnetoresistive stack. The magnetoresistive stack includes the various regions or layers that make up free and fixed regions of the device as well as one or more intermediate regions (e.g., dielectric layers) that separate these free and fixed regions, and in some cases, provide at least one tunnel junction for the device. In many instances, the layers of material in the magnetoresistive stack may be relatively very thin, e.g., on the order of a few or tens of angstroms. The term free refers to ferromagnetic regions having a magnetic moment that may shift or move significantly in response to applied magnetic fields or spin-polarized currents used to switch the magnetic moment vector of a free region. And, the term fixed refers to ferromagnetic regions having a magnetic moment vector that does not move substantially in response to such applied magnetic fields or spin-polarized currents.

In some applications, magnetoresistive devices may be included on the same integrated circuit with additional surrounding circuitry. For example, magnetoresistive devices (MRAMs, magnetic sensors, magnetic transducers, etc.) may be included on an integrated circuit with a microcontroller or other processing circuitry configured to utilize the information collected by, or stored in, the magnetoresistive devices.

### BRIEF DESCRIPTION OF THE DRAWINGS

Embodiments of the present disclosure may be implemented in connection with aspects illustrated in the attached drawings. These drawings show different aspects of the present disclosure and, where appropriate, reference numerals illustrating like structures, components, materials, and/or elements in different figures are labeled similarly. It is understood that various combinations of the structures, components, and/or elements, other than those specifically shown, are contemplated and are within the scope of the present disclosure.

For simplicity and clarity of illustration, the figures depict the general structure and/or manner of construction of the various embodiments/aspects described herein. Further, the figures depict the different layers/regions of the illustrated stacks as having a uniform thickness and well-defined boundaries with straight edges. However, a person skilled in the art would recognize that, in reality, the different layers typically may have a non-uniform thickness. And, at the interface between adjacent layers, the materials of these layers may alloy together, or migrate into one or the other material, making their boundaries ill-defined. Descriptions and details of well-known features (e.g., interconnects, etc.) and techniques may be omitted to avoid obscuring other features. Elements in the figures are not necessarily drawn to scale. The dimensions of some features may be exaggerated relative to other features to improve understanding of the exemplary embodiments. Cross-sectional views are simplifications provided to help illustrate the relative positioning of various regions/layers and describe various processing steps. One skilled in the art would appreciate that the cross-sectional views are not drawn to scale and should not be viewed as representing proportional relationships between different regions/layers. Moreover, while certain features are illustrated with straight 90-degree edges, in reality such features may be more “rounded” and/or gradually sloping or tapered.

Further, one skilled in the art would understand that, although multiple layers with distinct interfaces are illustrated in the figures, in some cases, over time and/or exposure to high temperatures, materials of some of the layers may migrate into or interact with materials of other layers to present a more diffuse interface between these layers. It should be noted that, even if it is not specifically mentioned, aspects described with reference to one embodiment may also be applicable to, and may be used with, other embodiments.

FIG. 1 is cross-sectional illustration of a portion of an exemplary integrated circuit device, according to one or more embodiments of the present disclosure;

FIGS. 2-8 are cross-sectional illustrations of a portion of an integrated circuit device at different stages of an exemplary manufacturing process, according to one or more embodiments of the present disclosure;

FIGS. 9 and 10 are schematic illustrations of exemplary magnetoresistive stack integration schemes, according to one or more embodiments of the present disclosure;

FIG. 11 is a flow chart illustrating an exemplary fabrication process for manufacturing a magnetoresistive structure, according to one or more embodiments of the present disclosure;

FIG. 12 is a schematic diagram of an exemplary magnetoresistive memory stack electrically connected to a select device, e.g., an access transistor, in a magnetoresistive memory cell configuration, according to one or more embodiments of the present disclosure;

FIGS. 13A and 13B are schematic block diagrams of integrated circuits including a discrete memory device and an embedded memory device, respectively, each including an MRAM (which, in one embodiment is representative of one or more arrays of MRAM having a plurality of magnetoresistive memory structures according to aspects of certain embodiments of the present disclosure); and

FIG. 14 is critical dimension scanning electron micrograph of a plurality of vias, according to one or more embodiments of the present disclosure.

### DETAILED DESCRIPTION

There are many embodiments described and illustrated herein. The present disclosure is neither limited to any single aspect nor embodiment thereof, nor to any combinations and/or permutations of such aspects and/or embodiments. Moreover, each aspect of the present disclosure, and/or embodiments thereof, may be employed alone or in combination with one or more of the other aspects of the present disclosure and/or embodiments thereof. For the sake of brevity, certain permutations and combinations are not discussed and/or illustrated separately herein. Notably, an embodiment or implementation described herein as “exemplary” is not to be construed as preferred or advantageous, for example, over other embodiments or implementations; rather, it is intended reflect or indicate that the embodiment(s) is/are “example” embodiment(s). Further, even though the figures and this written disclosure appear to describe a particular order of construction (e.g., from bottom to top), it is understood that the depicted structures may have the opposite order (e.g., from top to bottom), or a different order.

Unless defined otherwise, all terms of art, notations and other scientific terms or terminology used herein have the same meaning as is commonly understood by one of ordinary skill in the art to which this disclosure belongs. Some of the components, structures, and/or processes described or referenced herein are well understood and commonly employed using conventional methodology by those skilled in the art. Therefore, these components, structures, and processes will not be described in detail. All patents, applications, published applications and other publications referred to herein are incorporated by reference in their entirety. If a definition or description set forth in this disclosure is contrary to, or otherwise inconsistent with, a definition and/or description in these references, the definition and/or description set forth in this disclosure prevails over those in the references that are incorporated herein by reference. None of the references described or referenced herein is admitted to be prior art to the current disclosure.

An integrated circuit device may include conductive layers that are deposited and patterned to form connective traces, circuits, magnetoresistive devices, and interlayer connections. Circuits, magnetoresistive devices, and other components of the integrated circuit device (e.g., transistors, capacitors, diodes, etc.) may be coupled using structures within metal layers and via layers. To increase capacity and/or performance of the integrated circuit device, it may be desirable to create integrated circuit devices with a high density of components.

High-density integrated circuit devices may include multiple vertically stacked levels of interconnects (e.g., metal layers and/or vias). Each of the metal layers may be separated from other metal layers by one or more dielectric materials (e.g., interlayer dielectrics) that electrically isolate the metal layers from each other. Vias between the different metal layers may provide electrical connection between the different metal layers. A via may provide electrical connectivity between two adjacent metal layers, and may include electrically conductive material disposed in an aperture of the interlayer dielectric between two metal layers. For example, vias may connect features within a first metal layer (e.g., M1 layer) to the features within a second metal layer (e.g., M2 layer).

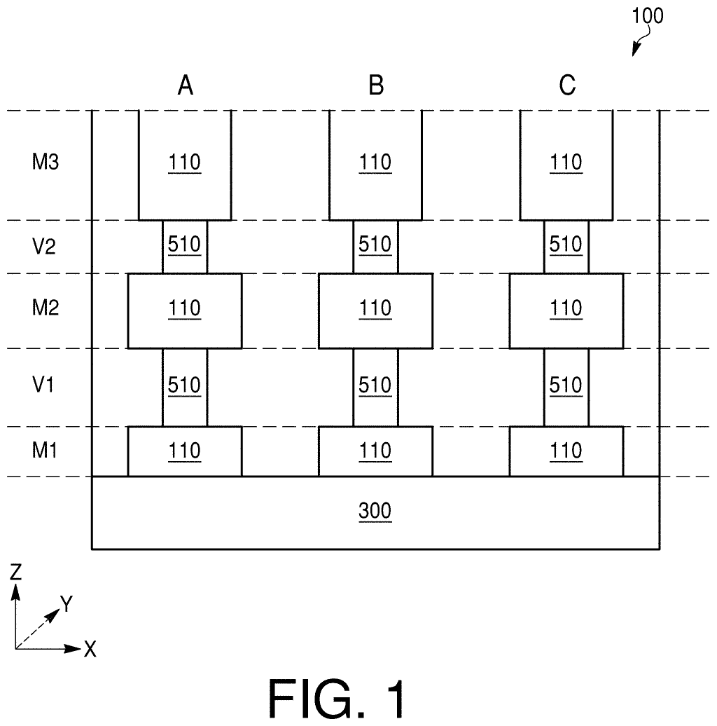

Referring to FIG. 1, a cross-sectional view of a portion of an integrated circuit device 100 is shown. The integrated circuit device 100 includes a plurality of vertically stacked levels of metals layers (e.g., M1, M2, and M3) and via layers (e.g., V1 and V2) formed on a substrate 800. The substrate 800 may be a semiconductor substrate including complementary metal-oxide-semiconductor (CMOS) circuitry.

The metal layers and via layers may be labeled according to their relative position to substrate 800. For example, M1, M2, and M3 correspond to the first three metal layers of the integrated circuit device 100, where M1 is the metal layer closest to substrate 800. V1 vias 510 connect features 110 of the M1 metal layer with features 110 of the M2 metal layer, and V2 vias 510 connect features 110 of the M2 metal layer with features 110 of the M3 metal layer. In this context, feature 110 may include a trace, pad, or other connection point in the corresponding metal layer. In some embodiments, features 110 and vias 510 may have a substantially circular cross-sectional shape. However, in general, these structures may have any cross-sectional shape (square, rectangular, etc.).

Still referring to FIG. 1, the vertical structures (labeled A, B, and C) formed by interconnected features 110 of metal layers and vias 510 illustrate exemplary circuitry associated with logic circuits, magnetoresistive devices, or other component of the integrated circuit device 100. A magnetoresistive device, for example, a magnetic tunnel junction memory device, may be integrated into a metal layer or between metal layers (e.g., within a via layer) of one or more of the vertical structures. The vias 510 and features 110 of metal layers surrounding the magnetoresistive device may provide electrical connectivity to the magnetoresistive device. For example, one or more of the vertical structures may include a magnetoresistive device within the M2 metal layer. In that example, the V1 via 510 and V2 via 510 adjoining the magnetoresistive device provide electrical connectivity between the magnetoresistive device and the rest of integrated circuit device 100. As described in greater detail below, a via 510 (e.g., the V1 via 510) connecting an adjoining magnetoresistive device to a feature 110 of an underlying metal layer may be referred to as an mvia.

The cross-sectional view shown in FIG. 1 is a cross section of the X-Z plane of an integrated circuit device 100. The height (or thickness) of the device 100 is shown vertically along the z-axis. Although only three vertical structures (A, B, and C) are shown in the portion of the device 100 illustrated in FIG. 1, a person of ordinary skill would recognize that an integrated circuit device 100 may include hundreds, thousands, or any number of vertical structures comprising features 110, vias 510, and/or magnetoresistive devices. Additional vertical structures representing circuit components of the integrated circuit device 100 may be located adjacent to the structures shown in FIG. 1, either along the y-axis (into and out of the page) or along the x-axis. Although not shown in FIG. 1, each metal layer may include interconnects (e.g., elongate interconnects) that extend within an X-Y plane and horizontally connect adjacent vertical structures.

The illustrated dimensions and arrangement of features 110 and vias 510 shown in FIG. 1 are only one example. Other dimensions and arrangements of features 110 and vias 510 may be incorporated. For example, the features 110 of metal layers in proximity to substrate 800 (e.g., M1) may have smaller dimensions (e.g., smaller widths and/or heights) than features of higher-level metal layers (e.g., M3). In some embodiments, the height of a via layer may be only about one-half to two-thirds of the height of an adjacent metal layer.

An integrated circuit device 100 may have any suitable number of metal layers. Although the specific embodiments presented herein may describe an integrated circuit device 100 with a particular number of metal layers, this is only exemplary. While a basic integrated circuit device may consist of only a few levels of metal layers (e.g., 2-4), a more complex integrated circuit device may include more levels of metal layers (e.g., 5-10, or more). Lower-level metal layers and via layers (i.e., M1, V1, or other layers close to substrate 800) may have smaller dimensions than higher-level metal layers and via layers. For example, features 110 of lower-level metal layers may attach to densely concentrated components with small dimensions (e.g., components of underlying CMOS circuitry). Vias 510 connecting to the features 110 having small dimensions must also be designed with small dimensions, to ensure a suitable connection.

As previously described, a magnetoresistive device may be incorporated within a vertical structure of the integrated circuit device 100. A magnetic via (also referred to as an mvia) may be used to integrate a magnetoresistive device within integrated circuit device 100. The mvia may couple an bottom electrode of the magnetoresistive device to a feature 110 of an underlying metal layer (e.g., M1). In some embodiments, for example, where magnetoresistive devices are integrated above the M1 layer, the corresponding mvias have relatively small dimensions compared to other components of the integrated circuit device 100. For example, an mvia may have a width of approximately 20 nanometers (nm) to approximately 100 nm, such as, for example, approximately 20 nm to approximately 80 nm, approximately 20 nm to approximately 75 nm, approximately 30 nm to approximately 100 nm, approximately 30 nm to approximately 80 nm, less than approximately 100 nm, less than approximately 80 nm, or less than approximately 65 nm.

Conventional means of forming small dimension interconnects (e.g., mvias) include the Damascene process and the Duel Damascene process, which include depositing dielectric material, etching an hole within the dielectric material, depositing insulating material, depositing a seed layer of conductive material, and electrochemical deposition of conductive material for the interconnect, followed by chemical mechanical planarization (CMP). As the dimensions of interconnects decrease, the Damascene processes have decreased accuracy and increased failure rates. Additionally, determining the proper etch chemistry to etch the dielectric hole, and determining compatible deposition steps for the conductive material may present additional challenges in utilizing a Damascene process for forming interconnects with small dimensions (e.g., mvias). Methods of the present disclosure may allow for means of forming a small dimension interconnect (e.g., an mvia) independent of a Damascene process.

Further, processing of layers above the mvia (e.g., layers that constitute the magnetoresistive stack) may redeposit electrically conductive material from the mvia onto the sidewalls of the magnetoresistive stack. This is particularly problematic in the case of vias formed with a Damascene process, because the metals used in the Damascene process create shorts when redeposited on the sidewalls of the magnetoresistive stack. Methods of the present disclosure also allow for the processing of layers above the mvia without redeposition of the conductive material from the mvia.

Methods of the present disclosure may include blanket deposition of barrier material followed by blanket deposition of contact material on an exposed feature 110 of a metal layer (e.g., M1). Segments of barrier material and contact material may form a via contacting the feature 110. The size of the via (e.g., mvia) may be defined by photolithography, followed by an etch stopping on the barrier material or feature 110 of the metal layer.

The fabrication of integrated circuits, microelectronic devices, micro electro mechanical devices, microfluidic devices, and photonic devices may involve the creation of several layers of materials that interact in some fashion. One or more of these layers may be patterned so various regions of the layer have different electrical or other characteristics, which may be interconnected within the layer or to other layers to create electrical components and circuits. These regions may be created by selectively introducing or removing various materials. The patterns that define such regions are often created by lithographic processes.

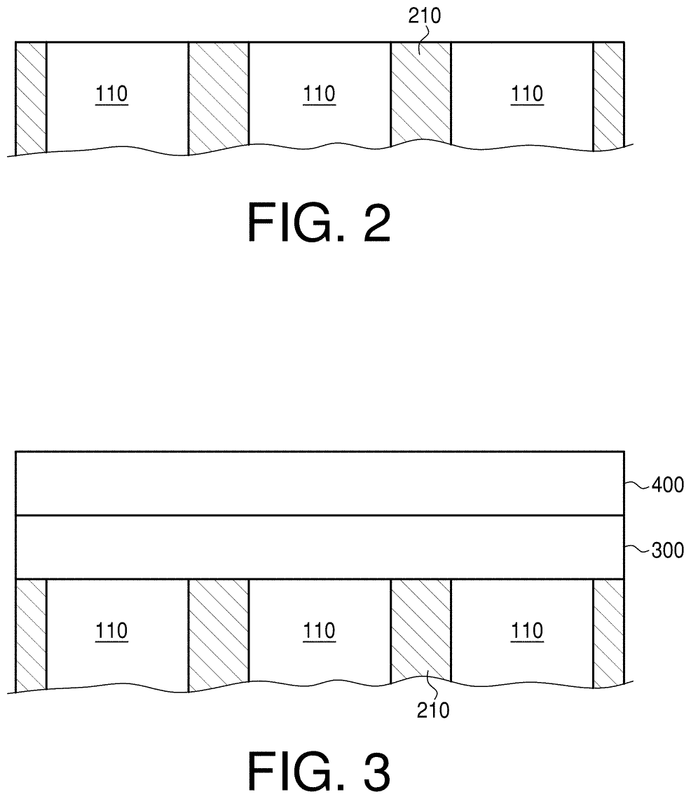

An exemplary method of manufacturing an integrated circuit device 100 is described below, with reference to FIGS. 2-8. Since different processes (e.g., deposition techniques, etching techniques, polishing techniques, etc.) involved in the manufacturing of integrated circuit devices 100 are well known in the art, detailed description of these techniques is omitted for the sake of brevity. The method described herein includes the formation of a via 510 above a feature 110 of a metal layer. The processing of the metal layer, and the layers below metal layer, may be performed using conventional integrated circuit fabrication processes known in the art. Therefore, for the sake of brevity, processing of the integrated circuit device 100 below the via 510 (e.g., processing of the metal layer and underlying layers) is not described in detail herein.

FIGS. 2-8 are simplified cross-sectional views at different stages during an exemplary fabrication process of an integrated circuit device 100. FIG. 2 shows a portion of an integrated circuit device 100 including features 110 of a metal layer.

As explained above, since conventional processing steps are used to fabricate the device up to the metal layer (e.g., M1), these processing steps will not be described in detail. Briefly, metal patterns, or features 110, corresponding to the metal layer are formed (deposited, patterned, etched, etc.) on the back end a semiconductor substrate 800 (see FIG. 1) having CMOS circuitry. These features 110 may be made of any electrically conductive material (copper, aluminum, tantalum, tantalum nitride, suitable alloys, etc.) and may include any type of feature 110 (such as, for example, a landing pad, conductive trace, etc.) that provides electrical connection to underlying CMOS circuitry. These features 110 may be formed using known lithographic and deposition steps.

Referring to FIG. 2, an individual feature 110 within a single metal layer may be isolated from other features 110 by interlayer dielectric material (ILD) 210. ILD 210 may include traditional ILD materials such as, for example tetraethyl orthosilicate (TEOS) or SiO₂. In addition, or alternatively, ILD 210 may include low-k ILD material, such as, for example, carbon doped SiO₂ (SiOC), carbon doped oxide (CDO), organo-silicate glass (OSG), spin-on organics, or other suitable dielectric material. Although a single ILD 210 is illustrated in FIG. 2, this is only exemplary. In some embodiments, multiple ILDs may be used. For example, some regions of the device (e.g., metal layers or portions of metal layers) may use one ILD (e.g., TEOS or SiO₂) and other regions of the device may use another ILD (e.g., a low-k ILD). See, for example, U.S. Pat. No. 10,950,657, which is incorporated by reference herein in its entirety.

Referring to FIG. 3, a method of forming a via 510 may include the blanket deposition of a layer of barrier material 300, and a layer of contact material 400. The layer of barrier material 300 and layer of contact material 400 may be deposited one over the other (i.e., sequentially). The layer of barrier material 300 may be deposited on a planarized surface including ILD 210 and features 110 of a metal layer. The layer of contact material 400 may be deposited on the layer of barrier material 300.

The layer of barrier material 300 may be deposited at a thickness of approximately 5 nm to approximately 30 nm, such as, for example, less than approximately 30 nm, 5 nm to 20 nm, or 10 nm to 20 nm. The layer of contact material 400 may be deposited at a thickness of approximately 20 nm to approximately 100 nm, such as, for example, less than approximately 100 nm, approximately 20 nm to approximately 75 nm, approximately 40 nm to approximately 100 nm, or approximately 30 nm to approximately 75 nm.

The barrier material may comprise titanium, tantalum, titanium nitride, tantalum nitride, copper, ruthenium, or a combination thereof.

The contact material may comprise cobalt, tantalum, ruthenium, aluminum, such as for example, aluminum doped with one or more elements (e.g., copper), tantalum nitride, or a combination thereof.

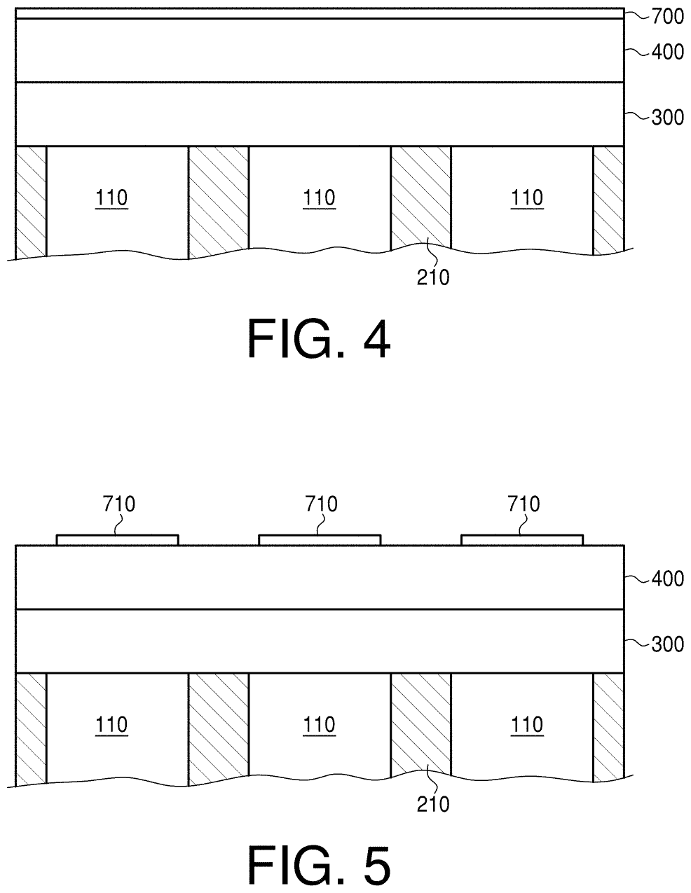

Referring to FIG. 4, after the layer of barrier material 300 and the layer of contact material 400 are formed, a photoresist 700 may be deposited above the layer of contact material. The photoresist 700 may include a photoresist of a photoresist and bottom anti reflective coating (BARC+PR) system, tri-layer resist (e.g., including a low temperature oxide and/or near frictionless carbon) system, or other suitable photoresist material.

Referring to FIG. 5, a mask containing clear and opaque areas may be used to selectively expose the photoresist 700 to a form of radiation, such as for example, an electron beam or electromagnetic radiation (e.g., ultraviolet light, x-rays, etc.). The mask may include a binary mask, a phase shift mask (e.g., attenuated phase shift mask or complementary phase shift mask), a chromeless phase lithography mask, or a combination thereof. The mask may permit radiation to regions of the integrated circuit device to pattern, or define, structures of the integrated circuit device, such as, for example, a via 510.

Either photoresist that is exposed to radiation, or photoresist that is not exposed to radiation, may be removed by the application of a developer. The remaining components of the photoresist 700 may constitute a guide 710, which may provide a template for one or more subsequent etching steps.

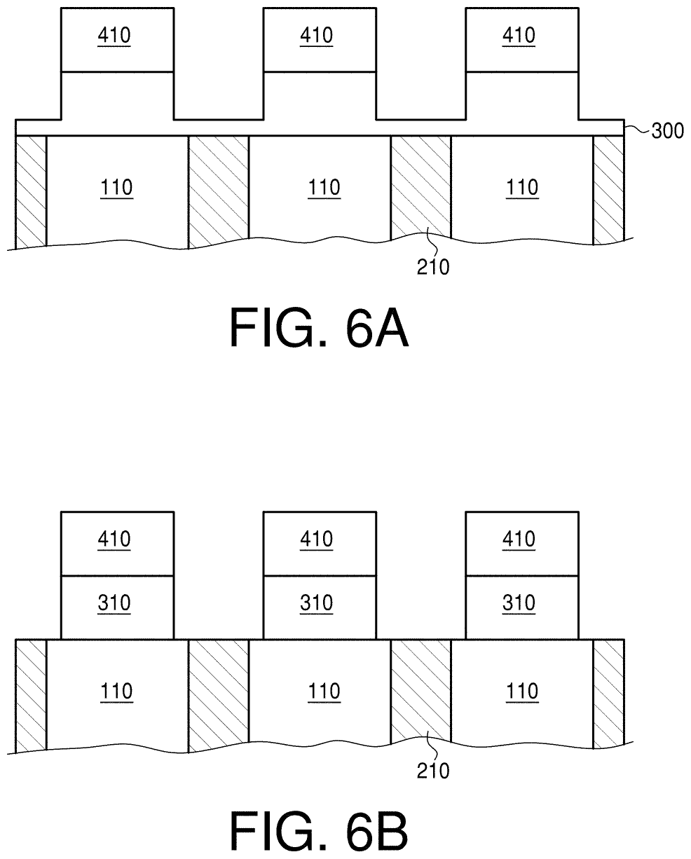

Referring to FIGS. 6A and 6B, after portions of photoresist 700 are developed and guide 710 is formed, a portion of the layer of barrier material 300 and a portion of the layer of contact material 400 may be removed. For example, the portion of the layer of barrier material 300 and a portion of the layer of contact material 400 may be etched by one or more etching processes. The one or more etching processes may include reactive ion etching, ion beam etching, sputtering, physical etches, or combinations thereof. Gases used in the one or more etching processes may include CF₄, CHF₄, O₂, N₂, Cl₂, BCl₃, argon, other suitable etching gases, or a combination thereof. The etch chemistry may be selected to ensure minimal or no damage of the feature 110 of the metal layer.

The guide 710 may function as a template for removing portions of the layer of barrier material 300 and the layer of contact material 400. For example, guide 710 may block the etch of material below guide 710. Sections of the layer of barrier material 300 and the layer of contact material 400 not etched may form a via 510 connecting to the feature 110 of the underlying metal layer. Each via 510 may include a barrier segment 310 and a contact segment 410.

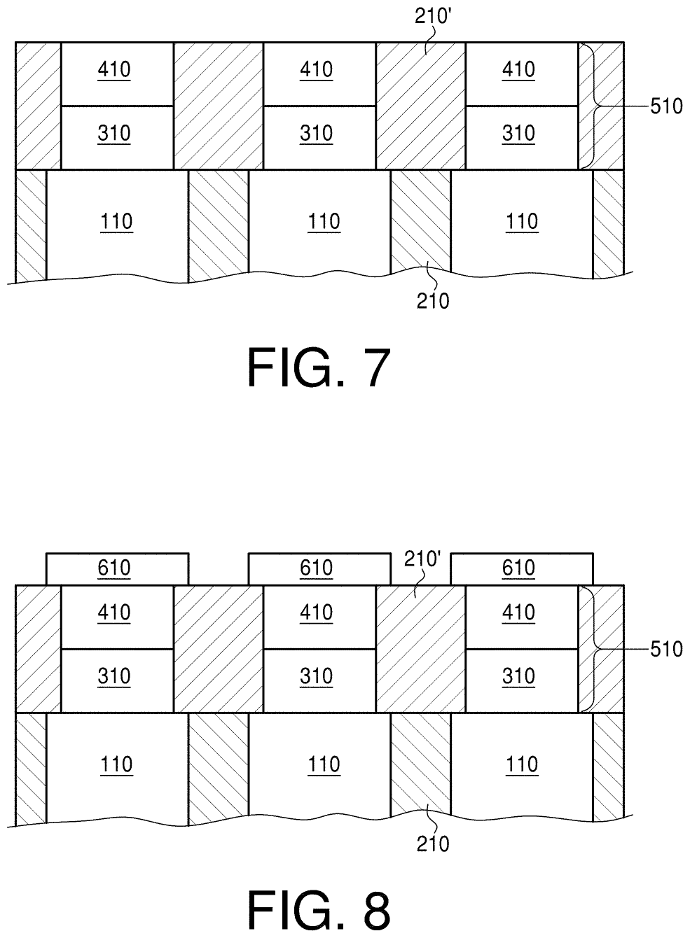

Referring to FIG. 6A, the etching may terminate within the layer of barrier material 300. After the termination of the etch within the layer of barrier material 300, remaining fragments of the layer of barrier material 300 between contact segments 410 may be removed in one or more additional etch processes, to form individual vias 510 (see FIGS. 7 and 8).

Referring to FIG. 6B, removing the portion of the layer of barrier material 300 and the portion of the layer of contact material 400 may include exposing a portion of feature 110 of an underlying metal layer. For example, the etching process used to remove the portion of the layer of barrier material 300 and the portion of the layer of contact material 400 may terminate at the metal layer (e.g., feature 110 and ILD 210). Regardless of where the etching defined by guide 710 terminates, the guide 710 is removed after etching is complete.

In some embodiments, the layer of contact material 400 may be deposited directly a planarized surface including ILD 210 and features 110 of a metal layer, without prior deposition of a layer of barrier material 300. In such embodiments, layer of contact material 400 may contact features 110 of the metal layer. The resulting vias 510 formed in these embodiments may include a contact segment 410, but not a barrier segment 310.

Referring to FIG. 7, after the vias 510s are formed, ILD 210′ may be deposited between vias 510. ILD 210′ may have the same composition as ILD 210, or ILD 210′ may have a different composition than ILD 210. After ILD 210′ is deposited between vias 510, the top surface of ILD 210′ and vias 510 may be planarized, for example, via CMP.

Referring to FIG. 8, after vias 510 are formed, a magnetoresistive stack 610 may be formed above and in contact with a corresponding via 510. For example, blanket layers of materials constituting the magnetoresistive stack 610 may be deposited on the planarized surface including vias 510 (e.g., contact segments 410) and ILD 210′. The blanket layers may then be etched to form magnetoresistive stacks 610 corresponding to the vias 510. Magnetoresistive stack 610 may be coaxial to its corresponding via 510.

Magnetoresistive stack 610 may constitute a part of a magnetoresistive device incorporated into integrated circuit device 100. Magnetoresistive stack 610 may include a plurality of magnetic material regions separated by one or more intermediate layers. In some embodiments, the intermediate layers may comprise a dielectric material and may form one or more tunnel junctions. For example, a magnetoresistive stack 610 may include a dielectric layer positioned between a free magnetic region and a fixed magnetic region, to form a magnetic tunnel junction. One or more magnetic regions of the magnetoresistive stack 610 may include a synthetic antiferromagnetic (SAF) or synthetic ferromagnetic (SyF) structure.

Additional examples of suitable magnetoresistive stacks 610, methods of depositing the layers of material constituting the magnetoresistive stacks 610, and methods of etching the layers of material to form magnetoresistive stacks 610, are described in U.S. Pat. Nos. 8,686,484; 8,747,680; 8,790,935; 8,877,522; 9,023,219; 9,136,464; 9,412,786; 9,419,208; 9,548,442; 9,711,566; 9,722,174; 10,461,251; 10,483,460; 10,535,390; 10,622,552; 10,700,268; and 10,847,711, and U.S. Patent Application Publication Nos. 2019/0165253; 2019/0140167; 2019/0157549, each of which is incorporated by reference in its entirety.

As previously described, a via 510 may have a width (e.g., diameter) less than or equal to a width of a corresponding magnetoresistive stack 610. For example, magnetoresistive stack 610 may have a width less than or equal to approximately 125 nm, such as, for example, less than approximately 100 nm, approximately 25 nm to approximately 100 nm, or approximately 25 nm to approximately 80 nm.

A via 510 may have a width at least approximately 3 nm less than a width of its corresponding magnetoresistive stack 610, such as, for example, at least approximately 4 nm, at least approximately 5 nm, at least approximately 7 nm, at least approximately 10 nm, approximately 3 nm to approximately 10 nm, or approximately 3 nm to approximately 5 nm less than a width of its corresponding magnetoresistive stack 610.

As previously mentioned, etching of layers above the via 510 (e.g., layers of material constituting magnetoresistive stack 610) may result in material of via 510 being redeposited on the sidewalls of magnetoresistive stack 610. Methods of the present disclosure allow for fabrication of small dimension vias 510 comprising material that is less disruptive to magnetoresistive stack 610 (if redeposited), compared to vias 510 manufactured using a Damascene process. Additionally, because the width of magnetoresistive stack 610 is greater than or equal to the width of via 510, material of via 510 is not redeposited on the sidewalls of magnetoresistive stack 610 during subsequent etching steps.

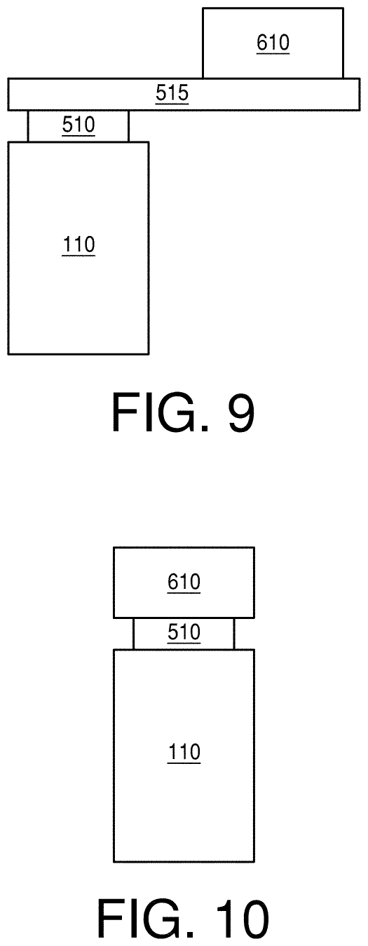

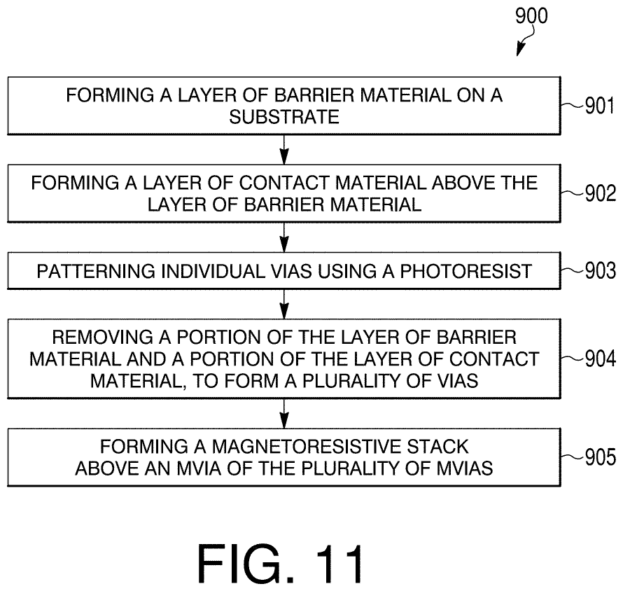

Magnetoresistive stacks 610 can be integrated with vias 510 without ensuring that the width of the magnetoresistive stack 610 is greater than the width of via 510, and without posing a risk of redeposition of via material on sidewalls of magnetoresistive stack 610. For example, referring to FIG. 9, a magnetoresistive stack 610 may be integrated off-axis to a feature 110 of the underlying metal layer. In off-axis integration, the magnetoresistive stack 610 is not coaxial to the feature 110 and via 510, and is connected to the via 510 by an elongate interconnect 515.

Methods of the present disclosure allow for on-axis integration of magnetoresistive stack 610 with via 510 and feature 110, with reduced or eliminated deleterious effects resulting from the redeposition of via material on sidewalls of the magnetoresistive stack 610. An example of on-axis integration is demonstrated in FIG. 10. The magnetoresistive stack 610 is coaxial to the via 510 and feature 110. On-axis integration allows for the manufacture of integrated circuit devices 100 with increased density of components, compared to off-axis integration.

The various regions or layers of integrated circuit device 100 may be deposited individually during manufacture. However, as would be recognized by those of ordinary skill in the art, the materials that make up the various regions may alloy with (intermix with and/or diffuse into) the materials of adjacent regions during subsequent processing (e.g., deposition of overlying layers, high temperature or reactive etching technique, and/or annealing).

Exemplary methods for forming an integrated circuit device according to embodiments of the present disclosure will now be discussed, and reference to parts and the numbered labels shown in FIGS. 1-8 may be made.

FIG. 10 is a flow chart of a method 900 of manufacturing an integrated circuit device 100, according to the present disclosure. A layer of barrier material 300 may be formed on a substrate (step 901). The substrate may include a silicon substrate, CMOS circuitry, one or more metal layers, and/or features 110 of a metal layer and ILD 210. A layer of contact material 400 may be formed above the layer of barrier material 300 (step 902). Individual vias 510 (e.g., mvias) may be patterned within the layer of barrier material 300 and layer of contact material 400 using a photoresist 700 (step 903). A portion of the layer of barrier material 300 and a portion of the layer of contact material 400 may be removed to form a plurality of vias 510 (step 904). For example, the portion of the layer of barrier material 300 and the portion of the layer of contact material 400 may be removed with a chemical etch or a physical etch. Next, method 900 may include forming a magnetoresistive stack 610 above a via 510 of the plurality of vias 510 (step 905).

A plurality of vias 510 were formed using methods described herein. The vias 510 were imaged using critical dimension scanning electron microscopy (CD-SEM). The CD-SEM generated image of the vias 510 is shown in FIG. 14.

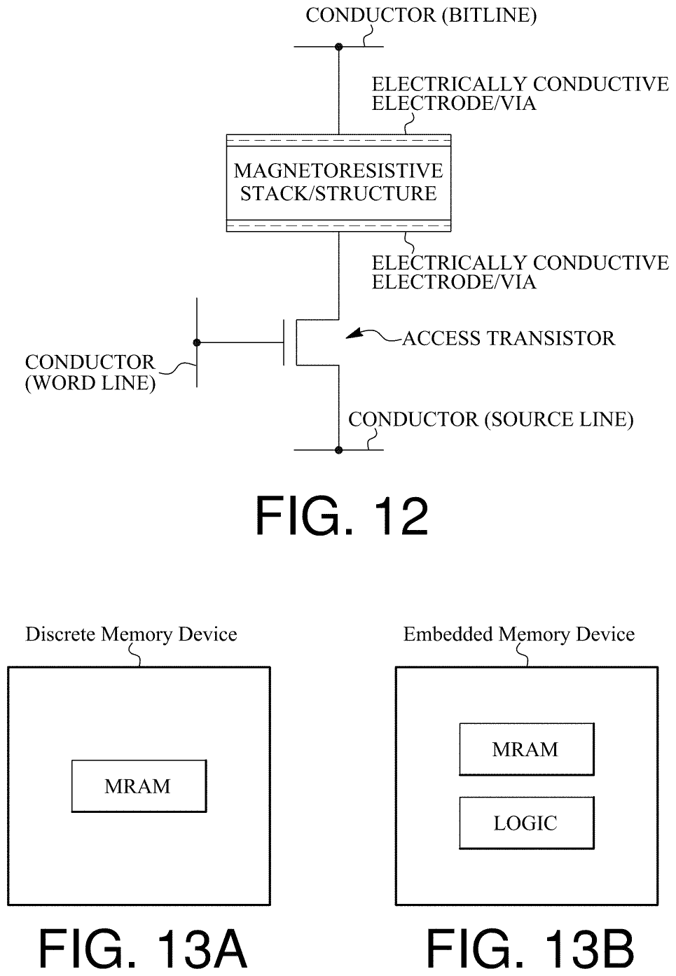

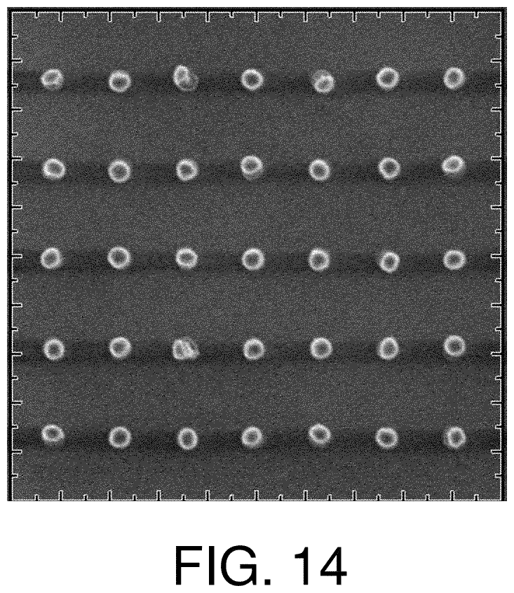

As alluded to above, the magnetoresistive devices (formed using aforementioned described techniques and/or processes) may include a sensor architecture or a memory architecture (among other architectures). For example, in a magnetoresistive device having a memory configuration, the magnetoresistive devices may be electrically connected to an access transistor and configured to couple or connect to various conductors, which may carry one or more control signals, as shown in FIG. 12. The magnetoresistive devices may be used in any suitable application, including, e.g., in a memory configuration. In such instances, the magnetoresistive devices may be formed as an IC device comprising a discrete memory device (e.g., as shown in FIG. 13A) or an embedded memory device having a logic therein (e.g., as shown in FIG. 13B), each including MRAM, which, in one embodiment is representative of one or more arrays of MRAM having a plurality of magnetoresistive devices formed magnetoresistive stacks/structures, according to certain aspects of certain embodiments disclosed herein.

In one embodiments, a method of manufacturing an integrated circuit device is disclosed. The method may include forming a layer of barrier material on a surface, where the surface includes interlayer dielectric and a feature of a metal layer. The method may further include forming a layer of contact material above the layer of barrier material, where the contact material includes aluminum, ruthenium, cobalt, tantalum, tantalum nitride, or a combination thereof. The method of manufacturing the integrated circuit device may further include removing a portion of the layer of barrier material and a portion of the layer of contact material to form a via. The method may further include depositing a magnetoresistive stack above, and in contact with, the via. In some embodiments, a width of the magnetoresistive stack is greater than or equal to a width of the via.

Various embodiments of the disclosed method may additionally or alternatively include one or more of the following features: the contact material includes aluminum doped with copper; the barrier material includes titanium, tantalum, titanium nitride, tantalum nitride, or a combination thereof; the magnetoresistive stack includes a synthetic antiferromagnetic or synthetic ferromagnetic structure; the width of the via is less than or equal to approximately 100 nanometers; the width of the magnetoresistive stack is at least approximately 3 nanometers greater than the width of the via; removing a portion of the layer of contact material includes etching a first region of the layer of contact material where the first region is contact with the feature of the metal layer, and etching a second region of the layer of contact material, where the second region is in contact with the interlayer dielectric. In some embodiments, the method may further comprise, after forming the layer of contact material, and prior to removing the portion of the layer of contact material: depositing a photoresist above the layer of contact material, and patterning the photoresist using a binary mask, a phase shift mask, or a chromeless phase lithography mask; where the portion of the layer of barrier material and the portion of the layer of contact material are defined by the patterned photoresist.

In another embodiment, a method of manufacturing an integrated circuit device is disclosed. The method may include forming a layer of barrier material on a surface, where the surface includes interlayer dielectric and a feature of a metal layer, and the barrier material includes titanium, tantalum, titanium nitride, tantalum nitride, or a combination thereof. The method may further include forming a layer of contact material above the layer of barrier material, where the contact material includes aluminum, ruthenium, cobalt, tantalum, tantalum nitride, or a combination thereof. The method may further include depositing a photoresist above the layer of contact material and patterning the photoresist. The method may further include removing a portion of the layer of barrier material and a portion of the layer of contact material to form a via having a width less than or equal to approximately 100 nanometers, where the portion of the layer of barrier material and the portion of the layer of contact material are defined by the patterned photoresist.

Various embodiments of the disclosed method may additionally or alternatively include one or more of the following features: where layers of material corresponding to a magnetoresistive stack include first layers of material that constitute a free region, second layers of material that constitute a fixed region, and a dielectric layer disposed between the first layer and second layer; where the magnetoresistive stack has a width that is at least approximately 3 nanometers great than the width of the via; where etching the layers of magnetic material does not redeposit material from the via onto the sidewalls of the magnetoresistive stack; where the patterning the photoresist includes patterning the photoresist using a binary mask, a phase shift mask, or a chromeless phase lithography mask; where the metal layer is a first metal layer, the integrated circuit device includes a plurality of metal layers above a silicon substrate, and the first metal layer is the metal layer that is closest to the silicon substrate. The method may further include depositing layers of material corresponding to a magnetoresistive stack, and etching the layer of material to form a magnetoresistive stack, where the magnetoresistive stack is coaxial to the via.

In another embodiment, a method of manufacturing an integrated circuit device is disclosed. The method may include forming a layer of barrier material above a metal layer, where the barrier material includes titanium, tantalum, titanium nitride, tantalum nitride, or a combination thereof, forming a layer of contact material above the layer of barrier material; removing a portion of the layer of barrier material and a portion of the layer of contact material to form a plurality of vias; depositing a second interlayer dielectric between vias of the plurality of vias; depositing layer of material corresponding to magnetoresistive stacks; and/or etching the layer of material to form a plurality of magnetoresistive stacks, where each magnetoresistive stack of the plurality of magnetoresistive stacks is in contact with a corresponding via of the plurality of vias.

Various embodiments of the disclosed method may additionally or alternatively include one or more of the following features: where layer of material corresponding to a magnetoresistive stack include first layers of material that constitute a free region, second layers of material that constitute a fixed region, and a dielectric layer, disposed between the first layers and the second layer; where each magnetoresistive stack of the plurality of magnetoresistive stacks is coaxial to its corresponding via; and/or where the width of at least one via of the plurality of vias is less than or equal to approximately 100 nanometers, and the width of the magnetoresistive stack corresponding to the at least one via is at least approximately 3 nanometers greater than the width of the at least one via.

Although various embodiments of the present disclosure have been illustrated and described in detail, it will be readily apparent to those skilled in the art that various modifications may be made without departing from the present disclosure or from the scope of the appended claims.

What is claimed is:

1. A method of manufacturing an integrated circuit device, the method comprising:
forming a layer of barrier material on a surface, where the surface includes interlayer dielectric and a feature of a metal layer;
forming a layer of contact material above the layer of barrier material, where the contact material includes aluminum, ruthenium, cobalt, tantalum, tantalum nitride, or a combination thereof;
removing a portion of the layer of barrier material and a portion of the layer of contact material to form a via; and
depositing a magnetoresistive stack above, and in contact with, the via;
where a width of the magnetoresistive stack is greater than or equal to a width of the via.

2. The method of claim 1, where the contact material includes aluminum doped with copper.

3. The method of claim 1, where the barrier material includes titanium, tantalum, titanium nitride, tantalum nitride, or a combination thereof.

4. The method of claim 1, where the magnetoresistive stack includes a synthetic antiferromagnetic or a synthetic ferromagnetic structure.

5. The method of claim 1, where the width of the via is less than or equal to approximately 100 nm.

6. The method of claim 5, where the width of the magnetoresistive stack is at least approximately 3 nm greater than the width of the via.

7. The method of claim 1, where removing a portion of the layer of contact material includes etching a first region of the layer of contact material, where the first region is in contact with the feature of the metal layer; and
etching a second region of the layer of contact material, where the second region is in contact with the interlayer dielectric.

8. The method of claim 7, further comprising, after forming the layer of contact material, and prior to removing the portion of the layer of contact material:
depositing a photoresist above the layer of contact material; and
patterning the photoresist using a binary mask, a phase shift mask, or a chromeless phase lithography mask;
where the portion of the layer of barrier material and the portion of the layer of contact material are defined by the patterned photoresist.

9. A method of manufacturing an integrated circuit device, the method comprising:
forming a layer of barrier material on a surface, where the surface includes interlayer dielectric and a feature of a metal layer, and the barrier material includes titanium, tantalum, titanium nitride, tantalum nitride, or a combination thereof;
forming a layer of contact material above the layer of barrier material, where the contact material includes aluminum, ruthenium, cobalt, tantalum, tantalum nitride, or a combination thereof;
depositing a photoresist above the layer of contact material;
patterning the photoresist; and
removing a portion of the layer of barrier material and a portion of the layer of contact material to form a via having a width less than or equal to approximately 100 nm, where the portion of the layer of barrier material and the portion of the layer of contact material are defined by the patterned photoresist.

10. The method of claim 9, further comprising:
depositing layers of material corresponding to a magnetoresistive stack;
etching the layers of material to form a magnetoresistive stack, where the magnetoresistive stack is coaxial to the via.

11. The method of claim 10, where layers of material corresponding to a magnetoresistive stack include:
first layers of material that constitute a free region;
second layers of material that constitute a fixed region; and
a dielectric layer, disposed between the first layers and second layers.

12. The method of claim 10, where the magnetoresistive stack has a width that is at least approximately 3 nm greater than the width of the via.

13. The method of claim 12, where etching the layers of magnetic material does not redeposit material from the via onto the sidewalls of the magnetoresistive stack.

14. The method of claim 9, where the patterning the photoresist includes patterning the photoresist using a binary mask, a phase shift mask, or a chromeless phase lithography mask.

15. The method of claim 9, where the metal layer is a first metal layer, the integrated circuit device includes a plurality of metal layers above a silicon substrate, and the first metal layer is the metal layer that is closest to the silicon substrate.

16. A method of manufacturing an integrated circuit device, the method comprising
forming a layer of barrier material above a metal layer, where the barrier material includes titanium, tantalum, titanium nitride, tantalum nitride, or a combination thereof;
forming a layer of contact material above the layer of barrier material;
removing a portion of the layer of barrier material and a portion of the layer of contact material to form a plurality of vias;
depositing a second interlayer dielectric between vias of the plurality of vias;
depositing layers of material corresponding to magnetoresistive stacks; and
etching the layers of material to form a plurality of magnetoresistive stacks, where each magnetoresistive stack of the plurality of magnetoresistive stacks is in contact with a corresponding via of the plurality of vias.

17. The method of claim 16, further comprising, after forming a layer of contact material, and prior to removing a portion of the layer of contact material:
depositing a photoresist above the layer of contact material, where the photoresist includes a low temperature oxide, near frictionless carbon, or both; and
patterning the photoresist using a binary mask, a phase shift mask, or a chromeless phase lithography mask;
where the portion of the layer of barrier material and the portion of the layer of contact material are defined by the patterned photoresist.

18. The method of claim 16, where layers of material corresponding to a magnetoresistive stack include:
first layers of material that constitute a free region;
second layers of material that constitute a fixed region; and
a dielectric layer, disposed between the first layers and second layers.

19. The method of claim 16, where each magnetoresistive stack of the plurality of magnetoresistive stacks is coaxial to its corresponding via.

20. The method of claim 16, where the width of at least one via of the plurality of vias is less than or equal to approximately 100 nm; and
the width of the magnetoresistive stack corresponding to the at least one via is at least approximately 3 nm greater than the width of the at least one via.
